(19) United States
(12) Patent Application Publication
(10) Pub. No.: US 2025/0320113 A1
(43) Pub. Date: Oct. 16, 2025

(54) PLASMA SHIELDING FOR AN ELECTROSTATIC MEMS DEVICE

(71) Applicant: ASML Netherlands B.V., Veldhoven (NL)

(72) Inventors: Christian WAGNER, Duizel (NL); Marco Matheus Louis STEEGHS, Sevenum (NL); Marcus Adrianus VAN DE KERKHOF, Helmond (NL)

(73) Assignee: ASML Netherlands B.V., Veldhoven (NL)

(21) Appl. No.: 18/868,801

(22) PCT Filed: May 23, 2023
(86) PCT No.: PCT/EP2023/063719

§ 371 Date: Nov. 25, 2024

(30) Foreign Application Priority Data
Jun. 28, 2022 (EP) 22181489.0

(51) Int. Cl. B81B 7/00; F16J 15/447; G01B 11/26; G02B 26/08; G03F 7/00

(52) U.S. Cl. CPC B81B 7/0025; G01B 11/26; G02B 26/0858; G03F 7/70291; G03F 7/706849; B81B 2201/042; F16J 15/447

(57) ABSTRACT

A micro-electromechanical system, MEMS, device configured to actuate a first part relative to a second part, the MEMS device comprising: a first electrode and a second electrode configured such that, in use, application of a voltage to the first electrode and the second electrode would cause a force to be applied to the first part relative to the second part; and a first baffle configured to prevent ingress of a fluid or transmission of radiation from an environment outside of the MEMS device into a space occupied by the first electrode and the second electrode.

### CROSS-REFERENCE TO RELATED APPLICATIONS

This application claims priority of EP Application Serial No. 22181489.0 which was filed on 28 June 2022 and which is incorporated herein in its entirety by reference.

### FIELD

The present invention relates to micro-electromechanical system (MEMS) device configured to actuate a first part relative to a second part.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

It is known that a lithographic apparatus may be provided with one or more mirrors or mirror elements actuated by microelectromechanical systems (MEMS), for example, piezoelectric or capacitive MEMS systems.

Low-pressure gaseous hydrogen is typically used in lithographic apparatus to provide a cleaning effect by removing contaminants, for example hydrocarbons, from within the lithographic apparatus

In the presence of EUV radiation, gaseous hydrogen may form a plasma. The plasma may be formed near to components of the lithographic apparatus (or may be formed elsewhere and transported near to the components) and may damage or otherwise prevent proper functioning of the components. For example, plasma may provide a short between electrodes of a capacitive MEMS device preventing actuation thereof. As another example, plasma ions may react with atoms (e.g. silicone atoms) in components to produce a volatile compound which is subsequently transported away from the component (referred to as ‘hydrogen induced outgassing’).

It is an object of the present invention to mitigate the above problems.

### SUMMARY

In a first example described here-in there is a micro-electromechanical system, MEMS, device configured to actuate a first part relative to a second part, the MEMS device comprising: a first electrode and a second electrode configured such that, in use, application of a voltage to the first electrode and the second electrode would cause a force to be applied to the first part relative to the second part; and a first baffle configured to prevent ingress of a fluid or transmission of radiation from an environment outside of the MEMS device into a space occupied by the first electrode and the second electrode.

The fluid may be a plasma (e.g. hydrogen plasma) and/or a gas (e.g. gaseous hydrogen). Beneficially, the first baffle may prevent gaseous hydrogen within the space occupied by the first electrode and the second electrode from being exposed to radiation (e.g. EUV radiation) (thereby preventing hydrogen plasma from being formed). For example, the radiation may be radiation that is directed to a component of the MEMS device or affixed to the MEMS device. The first baffle may also prevent hydrogen plasma from being transported to the space occupied by the first electrode and the second electrode. Accordingly, the first baffle may prevent damage that could otherwise be caused by hydrogen plasma.

The device may further comprise a labyrinth seal comprising: the first baffle, wherein the first baffle is coupled with the first part; and a second baffle coupled with the second part.

Beneficially, the labyrinth seal may prevent the ingress of hydrogen plasma (or any other fluid which may damage the MEMS device) into the space occupied by the first electrode and the second electrode, thereby protecting the MEMS device from damage caused by the hydrogen plasma. The labyrinth seal may comprise silicone.

The first part may comprise the first electrode; the second part may comprise the second electrode; and the force applied to the first part relative to the second part in use may be due to a coulomb force created due to the voltage.

The MEMS device may be an electro-static MEMS device and, advantageously, the electro-static MEMS device may be protected from damage caused by hydrogen plasma. An electro-static MEMS device may alternatively be referred to as a capacitive MEMS device. A coulomb force may alternatively be referred to as an electro-static force.

A piezo-electric component may be provided between the first electrode and the second electrode and the force applied to the first part relative to the second part may be due to the piezo-electric component deforming due to the voltage.

The MEMS device may be a piezoelectric MEMS device and, advantageously, the piezoelectric MEMS device may be protected from damage caused by hydrogen plasma.

The first baffle may be electrically grounded.

The second baffle may be electrically grounded.

The first part may further comprise a mirror, such that the mirror is caused to move when the force is applied to the first part relative to the second part.

Beneficially, the position of the mirror may be adjusted through operation of the MEMS device providing a deformable mirror that is robust against damage from hydrogen plasma.

The first part and the first baffle may be integrally formed and the second part and the second baffle may be integrally formed.

The first baffle may be substantially opaque to electromagnetic radiation.

The second baffle may be substantially opaque to electromagnetic radiation.

The electromagnetic radiation may be EUV radiation or DUV radiation.

In a second example described here-in, there is a micro-mirror array comprising a plurality of the devices of the first example.

In a third example described here-in, there is a programmable illuminator comprising a micro-mirror array according to the second example for conditioning a radiation beam.

The programmable illuminator may further comprise a displacement control feedback system configured to determine for each mirror in the micro-mirror array a position of the mirror and to adjust a voltage applied to the associated electro-static or piezo-electric actuators based on the determined position and based on a predefined target position of the mirror.

In a fourth example described here-in, there is a lithographic apparatus arranged to project a pattern from a patterning device onto a substrate, comprising a programmable illuminator according to the third example for conditioning a radiation beam used to illuminate the patterning device and/or for conditioning a radiation beam used to measure a target structure on the substrate.

In a fifth example described here-in, there is an inspection and/or metrology apparatus, comprising a programmable illuminator according to the third example for conditioning a radiation beam used to measure a target structure on a substrate.

For example, the micro-mirror array in the programmable illuminator may be used to control or condition a spectral and/or spatial distribution of the light or radiation beam that is used by the inspection and/or metrology apparatus to measure a target structure, e.g. a mark (er), on the substrate in order to determine the position of that target structure for alignment purposes and/or in order to perform an overlay measurement.

In a sixth example described here-in, there is a method of constructing a device of the first example comprising: providing a substrate; forming a first part and a second part; forming a first electrode and a second electrode configured such that, in use, application of a voltage to the first electrode and the second electrode would cause a force to be applied to the first part relative to the second part; and forming a first baffle configured to prevent ingress of a fluid or transmission of radiation from an environment outside of the MEMS device into a space occupied by the first electrode and the second electrode.

The method may further comprise forming a second baffle. The method may further comprise electrically grounding the first and/or second baffle.

### BRIEF DESCRIPTION OF THE DRAWINGS

Embodiments of the invention will now be described, by way of example only, with reference to the accompanying schematic drawings, in which:

FIG. 1A depicts a lithographic system comprising a lithographic apparatus and a radiation source;

FIG. 1B depicts a known inspection and/or metrology apparatus;

FIG. 1C depicts a programmable illuminator for use in the inspection and/or metrology apparatus of FIG. 1B;

FIG. 2 depicts a cross-section view of an example of a piezo-electric micro-mirror system;

FIG. 3 depicts a cross-section view of an example of an electro-static micro-mirror system;

FIG. 4 depicts a perspective view of an example of a piezo-electric micro-mirror system;

FIG. 5 depicts a cross-section view of an example of an electro-static micro-mirror system comprising a labyrinth seal;

FIG. 6 depicts a cross-section view of an example of a piezo-electric micro-mirror system comprising a labyrinth seal;

FIG. 7 depicts a method of forming a micro-mirror array from a plurality of wafers; and

FIG. 8 depicts an alternative method of forming a micro-mirror array comprising a step of HF vapor etching;

### DETAILED DESCRIPTION

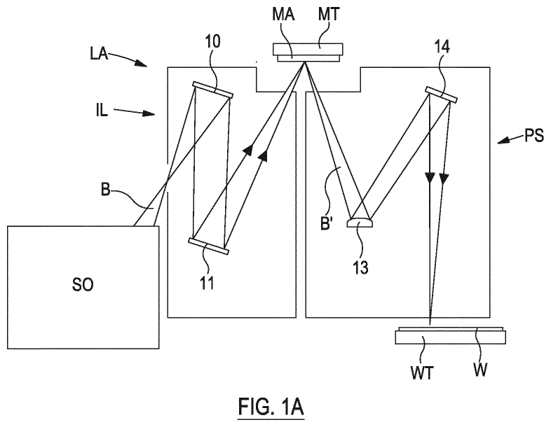

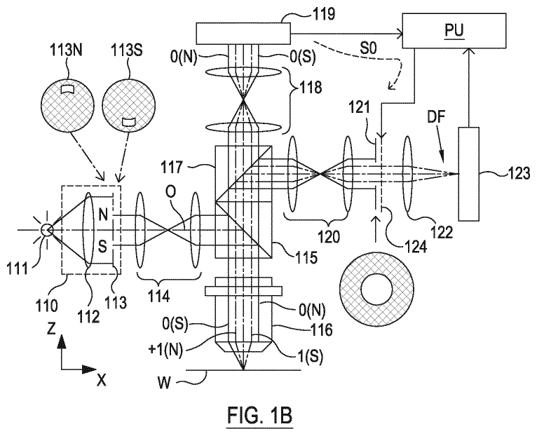

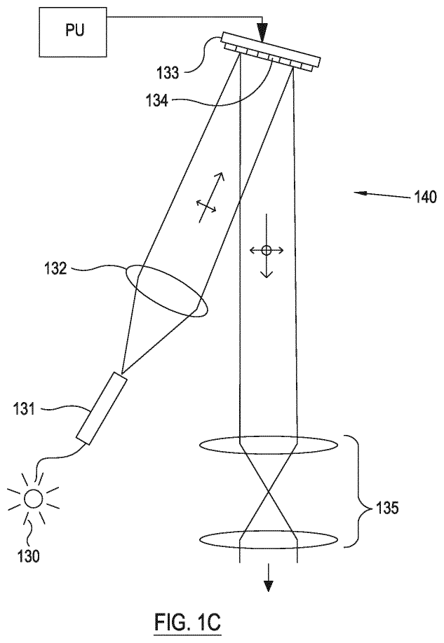

FIG. 1A shows a lithographic system comprising a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13,14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13, 14 in FIG. 1A, the projection system PS may include a different number of mirrors (e.g. six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e. a small amount of gas (e.g. hydrogen) at a pressure well below atmospheric pressure, may be provided in the lithographic apparatus (for example, the radiation source SO, in the illumination system IL, and/or in the projection system PS). The hydrogen may be provided by an inlet and removed by an outlet (not shown). The hydrogen gas may provide a cleaning effect (i.e. by removing contaminants from optical surfaces) and flow of hydrogen from the inlet towards the outlet may remove contaminants from within the lithographic apparatus.

The hydrogen gas may be exposed to the (unpatterned or patterned) EUV radiation beam B, B′. The EUV radiation beam B, B′ may provide sufficient energy to ionise the atoms in the hydrogen gas and so, under exposure to the EUV radiation beam B, B′, the hydrogen gas may be irradiated with sufficient energy to produce hydrogen plasma. Ions (e.g. H⁺, H²⁺ or H³⁺) in the hydrogen plasma May be accelerated (thereby increasing the energy of the ions), for example, by electric fields within the lithographic apparatus.

The ions in the hydrogen plasma may interact with the lithographic apparatus and the components therein. For example, hydrogen plasma may be produced in regions near to the components (where the regions near to the components are exposed to EUV radiation) and/or hydrogen plasma may be produced in regions away from, and subsequently transported near to, components. Multiple mechanisms of interaction (between the ions in the hydrogen plasma and the components of the lithographic apparatus LA) are possible, each of which cause damage to the components.

In a first example mechanism of interaction, electrostatic discharge effects damage or prevent normal operation of components. For example, (in normal operating conditions) a voltage May be applied across two electrodes of a microelectromechanical systems (MEMS) device to provide a force to actuate a first part of the MEMS device with respect to a second part of the MEMS device. Presence of a hydrogen plasma in a region near to or between the two electrodes may allow an electric current to flow between the two electrodes and thus prevent a sufficient voltage to be applied to actuate the MEMS device.

In a second example mechanism of interaction, in the event of the plasma ions interacting (by an elastic collision or otherwise) with a component, the momentum and kinetic energy of one or more atoms in the component may be increased. The increase in kinetic energy of the atom may allow the atom to escape from its chemical bonds and ‘sputter’.

In a third example mechanism of interaction, ions (i.e. free radicals) in the hydrogen plasma may react chemically with a component to form a volatile compound. As an example, solder joints may comprise tin or zinc and the tin or zinc may react chemically with the hydrogen plasma to form tin hydride or zinc hydride, respectively. As a further example, components may comprise silicone and the silicone may react chemically with the hydrogen plasma to form silane (SiH₄). The volatile compounds (e.g., tin hydride, zinc hydride or silane) may evaporate (or sublimate) and the component (e.g., solder joints) may degrade materially. The third example mechanism of interaction may also be referred to as ‘hydrogen-induced outgassing.’ Some of the volatile compounds produced in hydrogen-induced outgassing may cause further damage in other components of the lithographic system. For example, the tin hydride or zinc hydride may be transported to an optical surface (e.g. a reflective mirror surface of a mirror, such as, the facetted field mirror device 10 and the facetted pupil mirror device 11) and material (i.e. tin or zinc) may be deposited on the optical surface causing irreversible contamination.

While three example mechanisms of interaction have been described, as will be clear to the skilled person, the apparatus and methods taught herein may be used or adapted to mitigate or prevent damage to components (e.g. of the lithographic apparatus LA or otherwise) that may arise due to other mechanisms of interaction (between the hydrogen plasma and the components) or due to other causes of damage (i.e. other than hydrogen plasma).

The radiation source SO may be a laser produced plasma (LPP) source, a discharge produced plasma (DPP) source, a free electron laser (FEL) or any other radiation source that is capable of generating EUV radiation.

It is known in the art that one or more mirrors within the lithographic apparatus LA may be provided with a microelectromechanical system (MEMS) device to allow the mirror to be moved (i.e. tilted such that an angle of incidence between the mirror and the EUV radiation beam B, B′ is varied). As an example, the illuminator IL (discussed in more detail below) may be a programmable illuminator provided with one or more MEMS devices for actuating mirrors. Additionally, the mirror may be one of a plurality of mirrors, each of the plurality of mirrors being actuated by a respective MEMS device of a plurality of MEMS devices. In other words, a single mirror may be replaced by a micro-mirror array where each micro-mirror is actuated by a MEMS device such that each micro-mirror system (of the micro-mirror array) is independently moveable of the other micro-mirror systems in the micro-mirror array. As an example, the facetted field mirror device 10 and/or the facetted pupil mirror device 11 may comprise micro-mirror arrays. A micro-mirror array may allow correction of aberrations (or other distortions or undesirable optical effects) in a radiation beam being reflected by the micro-mirror array. Additionally or alternatively, a micro-mirror array may remove the need for additional mirrors elsewhere in the lithographic apparatus (for example, a ‘condenser’ mirror i.e. a mirror, not shown in FIG. 1A, used to project the EUV radiation beam B after the EUV radiation beam B has been reflected by the facetted pupil mirror device 11).

Each micro-mirror system may comprise a mirror (with a reflective mirror surface) fixed to a MEMS device. Alternatively, a side of the MEMS device may be provided with a reflective mirror surface. The reflective mirror surface may, optionally, be provided with one or more coatings to improve an optical property. Each MEMS device of the micro-mirror array may be fixed to a common substrate such that each micro-mirror system (in a micro-mirror array) shares a common backing.

Each MEMS device may comprise piezo-electric components and be actuated by piezo-electric effects. Additionally or alternative, each MEMS device may comprise two or more electrodes and may be actuated using electro-static (i.e. coulomb) forces. Together the micro-mirror and the MEMS device may be referred to as a micro-mirror system and a micro-mirror array may comprise one or more micro-mirror systems.

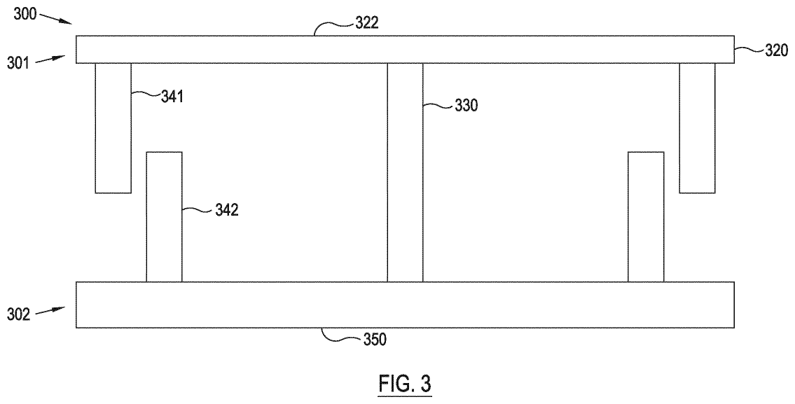

FIG. 1B shows an inspection and/or metrology apparatus that is known from U.S. Pat. No. 9,946,167 B2, which is hereby incorporated in its entirety by reference. FIG. 1B corresponds to FIG. 3a of U.S. Pat. No. 9,946,167 B2. The inspection and/or metrology apparatus is a dark field metrology apparatus for measuring e.g. overlay and/or alignment.

In lithographic processes, it is desirable to frequently make measurements of the structures created, e.g., for process control and verification. Various tools for making such measurements are known, including scanning electron microscopes, which are often used to measure critical dimension (CD), and specialized tools to measure overlay, the accuracy of alignment of two layers in a device and alignment, i.e. the position of alignment marks on the substrate. Various forms of scatterometers have been developed for use in the lithographic field. These devices direct a beam of radiation onto a target structure, e.g. a grating or mark(er), and measure one or more properties of the scattered radiation e.g., intensity at a single angle of reflection as a function of wavelength; intensity at one or more wavelengths as a function of reflected angle; or polarization as a function of reflected angle—to obtain a “spectrum” from which a property of interest of the target can be determined. Determination of the property of interest may be performed by various techniques: e.g., reconstruction of the target structure by iterative approaches such as rigorous coupled wave analysis or finite element methods; library searches; and principal component analysis

The dark field metrology apparatus shown in FIG. 1B may be a stand-alone device/system or may be incorporated in the lithographic apparatus LA as an alignment system and/or as an overlay measurement system (not shown). An optical axis, which has several branches throughout the apparatus, is represented by a dotted line 0. In this apparatus, light emitted by radiation source 111 (e.g., a xenon lamp) is directed onto a substrate W via a beam splitter 115 by an optical system comprising lenses 112, 114 and objective lens 116. These lenses are arranged in a double sequence of a 4F arrangement. Therefore, the angular distribution at which the radiation is incident on the substrate can be selected by defining a spatial intensity distribution in a plane that presents the spatial spectrum of the substrate plane, here referred to as a (conjugate) pupil plane. In particular, this can be done by inserting an aperture plate 113 of suitable form between lenses 112 and 114, in a plane which is a back-projected image of the objective lens pupil plane. In the example illustrated, aperture plate 113 has different forms, labeled 113N and 1135, allowing different illumination modes to be selected. The illumination system in the present example forms an off-axis illumination mode. In the first illumination mode, aperture plate 113N provides off-axis from a direction designated, for the sake of description only, as ‘north’. In a second illumination mode, aperture plate 1135 is used to provide similar illumination, but from an opposite direction, labeled ‘south’. Other modes of illumination are possible by using different apertures. The rest of the pupil plane is desirably dark, as any unnecessary light outside the desired illumination mode will interfere with the desired measurement signals.

A target structure (not shown), e.g. a grating or mark (er), on substrate W is placed normal to the optical axis 0 of objective lens 116. A ray of illumination impinging on the target structure from an angle off the axis 0 gives rise to a zeroth diffraction order ray and two first diffraction order rays. Since the aperture in plate 113 has a finite width (necessary to admit a useful quantity of light) the incident rays will in fact occupy a range of angles, and the diffracted rays 0 and +1/−1 will be spread out somewhat. According to the point spread function of a small target, each order +1 and −1 will be further spread over a range of angles, not a single ideal ray. Note that the grating pitches and illumination angles can be designed or adjusted so that the first order rays entering the objective lens are closely aligned with the central optical axis.

At least the 0 and +1 orders diffracted by the target on substrate W are collected by objective lens 116 and directed back through beam splitter 115. Both the first and second illumination modes are illustrated, by designating diametrically opposite apertures labeled as north (N) and south(S). When the incident ray is from the north side of the optical axis, that is when the first illumination mode is applied using aperture plate 113N, the +1 diffracted rays, which are labeled +1(N), enter the beams. Each diffraction order hits a different point on the sensor, so that image processing can compare and contrast orders. The pupil plane image captured by sensor 119 can be used for focusing the inspection and/or metrology apparatus and/or normalizing intensity measurements of the first order beam. The pupil plane image can also be used for many measurement purposes such as reconstruction.

In the second measurement branch, an optical system including lenses 120, 122 forms an image of the target on the substrate W on sensor 123 (e.g. a CCD or CMOS sensor). In the second measurement branch, an aperture plate referred to as field stop 121 is provided in a plane that is conjugate to the pupil-plane. This plane will be referred to as an ‘intermediate pupil plane’ when describing the invention. Field stop 121 functions to block the zeroth order diffracted beam so that the image of the target formed on sensor 123 is formed only from the −1 or +1 first order beam. The images captured by sensors 119 and 123 are output to image processor and controller PU, the function of which will depend on the particular type of measurements being performed. Note that the term ‘image’ is used here in a broad sense. An image of the grating lines as such will not be formed, if only one of the −1 and +1 orders is present.

The illumination system of the inspection and/or metrology apparatus comprises an illuminator 110. As shown in FIG. 1B, this illuminator 110 comprises lens 112 and aperture plate 113. More details of the inspection and/or metrology apparatus can be found in U.S. Pat. No. 9,946,167 B2.

FIG. 1C shows a programmable illuminator 140 for use in the inspection and/or metrology apparatus of FIG. 1B. This programmable illuminator 140 can be used in the inspection and/or metrology apparatus of FIG. 1B instead of the illuminator 110. The programmable illuminator 140 comprises a micro-mirror array 133 as well as a low NA relay 4F system 135 comprising a pair of lenses. Radiation or light from a radiation source 130 (not part of the programmable illuminator 140), e.g. a broad band radiation source or white light source, may be directed via an optional fiber 131 and an optional collimating lens system 132 to the micro-mirror array 133. A processing unit PU can control the micro-mirror array 133 in such a way that the micro-mirrors 134, or more precise the mirrors in the micro-mirrors 134, in the micro-mirror array 133 are tilted individually. By tuning the tilt angle of each individual mirror independently, the spatial distribution of the light that is output by the low NA relay system 135 can be controlled and various illumination modes can be made as desired without having to use aperture plates. If the programmable illuminator 140 is used in the inspection and/or metrology apparatus of FIG. 1B it interfaces with lenses 114, meaning that the light that is output by the low NA relay system 135 is received by the lenses 114 of FIG. 1B.

In order to control the spectral distribution of the light that is output by the low NA relay system 135 at least part of the mirrors may comprise a grating on top of the mirror surfaces (not shown). The grating may be the same for all mirrors or, alternatively, different gratings, e.g. gratings having different pitches, may be used. By appropriate control of the micro-mirror array 133 the light that is output by the low NA relay system 135 comprises a single wavelength or a single (narrow) range of wavelengths. It is however also possible to control the micro-mirror array 133 in such a way that the light that is output by the low NA relay system 135 comprises a number of different wavelengths or a number of different (narrow) ranges of wavelengths. The gratings may be lithographically patterned on the mirror surfaces. Each mirror with grating diffracts light of different wavelengths in different directions according to the associated grating equation. A portion of the diffracted light is captured by the low NA relay system 135 and an image is formed. By tuning the angle of each mirror independently, the light distribution at the output can be controlled both spatially and spectrally as (a) certain diffraction order(s) will be captured by the low NA relay system 135 and (an) other diffraction order(s) will not be captured. Such a spatial and spectral light distribution can be used advantageously for example for illuminating and measuring an overlay target structure on a substrate or for measuring the position of an alignment mark on a substrate. In this text, the terms target structure, target, mark, marker and grating are, where the context allows, all synonyms of each other.

The spectral bandwidth of the diffracting beam which can be captured by the low NA relay system 135 is dλ=P. NA where P is the pitch of the grating and NA is the numerical aperture of the low NA relay system 135. With P=500 nm and NA=0.02 the spectral bandwidth is 10 nm, meaning that a diffraction order of the grating comprises a range or band of wavelengths of 10 nm.

The spatial resolution of the low NA relay system 135 is ˜λ/NA. With λ=850 nm and NA=0.02 the spatial resolution is 42.5 micrometer. If the size of the mirrors is greater than 42.5 micrometer, each mirror can be resolved. A reasonable size of a mirror is 100×100 micrometer.

By rotating/tilting the mirrors around their individual axis, a different central wavelength band can be directed into the low NA relay system 135. The rotating range of each mirror required for operation over the visible wavelength range should be ˜Δλ/2P, where Δλ=400 nm for an operating wavelength range of 450 nm-850 nm. This means that each mirror must be able to rotate by 0.4 radians.

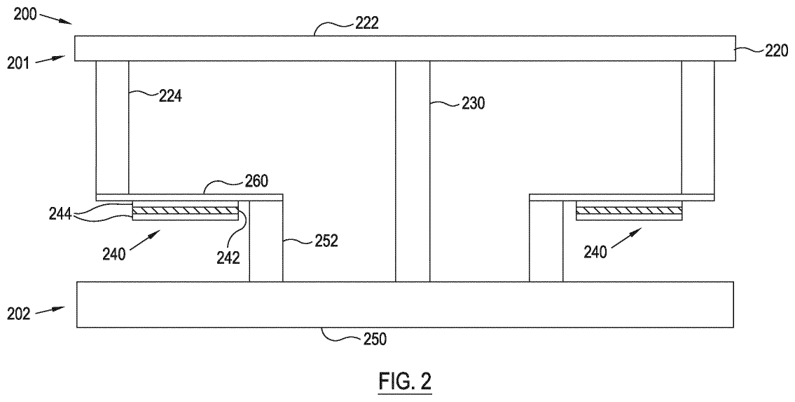

FIG. 2 shows a cross-section view of a simplified example piezo-electric micro-mirror system 200 (i.e. a system comprising a micro-mirror actuated by a MEMS device using the piezo-electric effect). The piezo-electric mirror system 200 comprises a first part 201 comprising a mirror 220 with a reflective mirror surface 222. A side of the mirror 220 opposed to the reflective mirror surface 222 is fixed to a first end of a central pillar 230. The central pillar 230 is typically fixed to a point approximately central to the side of the mirror 220 opposed to the reflective mirror surface 222. A second end of the central pillar 230 is fixed to a second part 202 comprising a substrate 250.

The central pillar 230 is resilient such that the central pillar 230 may deform allowing the position of the mirror 220 to move when a force is applied to the mirror 220. In other words, the central pillar 230 may act as a gimbal allowing the mirror 220 to tilt. The central pillar 230 may be a biasing member such that the mirror 220 is urged to a neutral, resting position when a force is no longer applied. While the central pillar 230 is depicted as a single pillar, the central pillar 230 may comprise multiple resilient members that together act as a gimbal allowing tilting in first and second directions without (or minimising) movement in a third direction.

The piezo-electric micro-mirror system 200 further comprises one or more piezo-electric actuators 240. Each piezo-electric actuator comprises one or more layers of a piezo-electric material 242 and two or more electrodes 244. In the example of FIG. 2, each pizeo-electric actuator consists of a single layer of piezo-electric material 242 provided (i.e. sandwiched) between two electrodes 244. In other examples, each piezo-electric actuator may be provided with multiple layers of piezo-electric material 242 and multiple electrodes 244, each layer of piezo-electric material 242 being provided between two electrodes 244. Under the application of a voltage provided by the electrodes 244, the piezo-electric material 242 may deform (due to the piezo-electric effect) exerting a force on components the piezo-electric actuator 240 is fixed to.

Each piezo-electric actuator 240 may be fixed, at a first end, to the mirror 220 and, at a second end, to the substrate 250. Alternatively, as can be seen by the example piezo-electric micro-mirror system 200, each of the piezo-electric actuators 240 may be fixed to components that are fixed (directly or indirectly) to the mirror 220 or fixed to the substrate 250. In the example piezo-electric micro-mirror system 200, each of the piezo-electric actuators 240 are fixed to a respective resilient member 260 (such that the layers of piezo-electric material 242 are aligned with the resilient member 260 as shown in FIG. 2). While the piezo-electric actuator 240 is fixed to a first face of the resilient member 260 (i.e. a face opposed to the substrate 202), the piezo-electric actuator 202 may alternatively be fixed to a second face of the resilient member 260 (i.e. a face opposed to the mirror 220). A plurality of first pillars 224 extend away (i.e. towards the substrate 250) from the mirror 220 and a plurality of second pillar 252 extend away (i.e. towards the mirror 220) from the substrate 250. Each of the first pillars 224 and each of the second pillars 252 may be shorter than the central pillar 230. A first end of each resilient member 260 is fixed to a respective first pillar 224 (of the plurality of first pillars 224) and a second end of each resilient member 260 is fixed to a respective second pillar 252 (of the plurality of second pillars 252).

The piezo-electric micro-mirror system 200 may comprise any number of piezo-electric actuators 240. The piezo-electric actuators 240 may be operated co-operatively in pairs (i.e. on opposing sides of the piezo-electric mirror system 200) and so the piezo-electric micro-mirror system 200 may comprise an even number of piezo-electric actuators 240, for example, two or four. Beneficially, providing the piezo-electric micro-mirror system 200 with at least four piezo-electric actuators allows the first part 201 comprising the mirror 220 to be tilted around two different axes.

As discussed above, under application of a voltage, the piezo-electric actuators 240 may deform by exerting a force against the first pillars 224 and the second pillars 252. By operating a piezo-electric actuator 240, the angle of the mirror 220 may be varied. A single piezo-electric actuator 240 may be operated, or, alternatively, multiple piezo-electric actuators 240 may be operated co-operatively. For example, by operating piezo-electric actuators 240 on opposing sides of the piezo-electric micro-mirror system 200 co-operatively (i.e. a first voltage is applied to a first piezo-electric actuator which deforms in a first direction and a second voltage, equal but opposite to the first, is applied to a second piezo-electric actuator, which deforms in a second direction, equal but opposite to the first), the angle of the mirror 220 (and the reflective mirror surface 222) may be varied. In other words, the mirror 220 may be tilted from a first position to a second position. The first position may be the neutral position, or alternatively, the first position may an intermediate position (i.e. a position that has been achieved through operation of at least one piezo-electric actuator 240).

After the application of the voltage has stopped (and the force is no longer applied), the central pillar 230 may urge the mirror 220 to the first position. Additionally or alternatively, an opposing voltage may be applied to each of the piezo-electric actuators for a time period sufficiently long to return the mirror 220 to the first position.

Additionally or alternatively, as discussed above, each MEMS device may comprise two or more electrodes and may be actuated using electro-static forces. In other words, each micro-mirror may be an electro-static micro-mirror system (i.e. a system comprising a micro-mirror actuated by a MEMS device using electro-static forces). As the force used to actuate the MEMS device of an electro-static micro-mirror system may use capacitance, an electro-static micro-mirror system may also be referred to as a capacitive micro-mirror system. FIG. 3 shows a cross-section view of a simplified example electro-static micro-mirror system 300 (i.e. a system comprising a micro-mirror actuated by a MEMS device using the electro-static effect).

Likewise to the piezo-electric mirror system 200, the electro-static micro-mirror system 300 comprises a first part 301 comprising a mirror 320 with a reflective mirror surface 322. A side of the mirror 320 opposed to the reflective mirror surface 322 is fixed to a first end of a central pillar 330. The central pillar 330 is typically fixed to a point approximately central to the side of the mirror 320 opposed to the reflective mirror surface 322. A second end of the central pillar 330 is fixed to a second part 302 comprising a substrate 350.

The central pillar 330 is resilient such that the pillar 330 may deform allowing the position of the mirror 320 to move when a force is applied to the mirror 320. In other words, the central pillar 330 may act as a gimbal allowing the mirror 320 to move. The central pillar 330 may be a biasing member such that the mirror 320 is urged to a neutral, resting position when a force is no longer applied.

The electro-static micro-mirror system 300 further comprises one or more first electrodes 341 and one or more second electrodes 342. Each of the first electrodes 341 may be fixed to (or be integral to) the mirror 320 and each of the second electrodes 342 may be fixed to (or be integral to) the substrate 350. Each of the first electrodes 341 may be offset, for example, axially offset (i.e. not axially aligned) radially offset or azimuthally offset with a respective second electrode 342. Additionally or alternatively, each electrode (i.e. the first electrode 341 and/or the second electrodes 342) may be a comb electrode (i.e. an electrode comprising a plurality of teeth) and each tooth of the first electrode 341 may be axially offset from a respective tooth of the second electrode 342.

The electro-static micro-mirror system 300 may comprise any number of electro-static actuators 340. By operating a electro-static actuator 340, the angle of the mirror 320 may be varied. A single electro-static actuator 340 may be operated, or, alternatively, the electro-static actuators 340 may be operated co-operatively in pairs (i.e. on opposing sides of the electro-static mirror system 300). Accordingly the electro-static micro-mirror system 300 may comprise an even number of electro-static actuators 340, for example, two or four. Beneficially, providing the electro-static micro-mirror system 300 with at least four piezo electro-static actuators (i.e. two pairs of piezo electro-static actuators 341, 342) allows the first part 301 comprising the mirror 320 to be tilted around two different axes.

Under application of a voltage across a first electrode 341 and a respective second electrode 342, an electrostatic force (i.e. a coulomb force) may be exerted between the first electrode 341 and second electrode 342. In an example in which electro-static actuators 340 are operated co-operatively, voltages may be applied between first electrodes 341 and second electrodes 342 on opposing sides of the electro-static micro-mirror system 300, the angle of the mirror 320 (and the reflective mirror surface 322) may be varied. In other words, the mirror 320 may be tilted from a first position to a second position.

After the application of the voltage has stopped (and the force is no longer applied), the central pillar 330 may urge the mirror 320 to the first position. Additionally or alternatively, an opposing voltage may be applied to each of the first electrodes 341 and second electrodes 342 for a time period sufficiently long to return the mirror 320 to the first position.

For simplicity, the piezo-electric micro-mirror system 300 and the electro-static micro-mirror system 400 have been depicted with a small number of electrodes 244, 341, 342. As will be clear to the skilled person, each of the electrodes 244, 341, 342 may be one of a respective plurality of electrodes (i.e. the first electrode 341 may be one of a plurality of first electrodes).

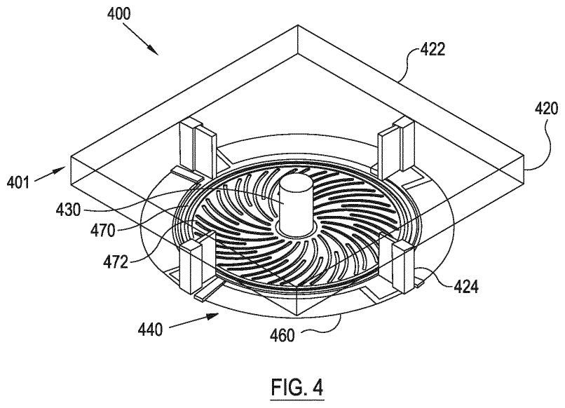

FIG. 4 depicts a perspective view of a piezo-electric micro-mirror system 400. Like the piezo-electric micro-mirror system 200, the piezo-electric micro-mirror system 400 comprises a first part 401 with a mirror 420 with a reflective mirror surface 422. A first end of a central pillar 430 is fixed to a side of the mirror 420 opposed to the reflective mirror surface 422. Four actuators 440 (obscured in FIG. 4) are fixed to an side of resilient members 460 and each resilient member 460 is fixed to one of four firsts pillars 424. The piezo-electric micro-mirror system 400 further comprises a heat sink 470 with groves 472. Other components of the piezo-electric micro-mirror system 400 are not shown for simplicity.

The micro-mirror system (i.e. either a piezo-electric micro-mirror system 200, 400 or an electro-static micro-mirror system 300) may further comprising electronics configured to determine the position of the mirror 320. For example, the electro-static micro-mirror system 300 may further comprise one or more third electrodes and one or more fourth electrodes. Each of the third electrodes may be fixed to (or be integral with) the mirror 320 and each of the fourth electrodes may be fixed to (or be integral with) the substrate 350. The third electrodes and the fourth electrodes may be provided closer to the central pillar 330 than the first electrodes 341 and second electrodes 342. Beneficially, positioning the first electrodes 341 and the second electrodes 342 in this way may improve a torque applied to the mirror 320. An electrical property (for example, a capacitance) may be measured across a third electrode 343 and a respective fourth electrode 344 and the measured electrical property may be used to determine the distance between the third electrode 343 and the respective fourth electrode 344. In this way, the angle of the mirror can be determined. As will be clear to the skilled person, the electronics configured to determine the position of the mirror may alternatively or additionally comprise piezo-electronics materials.

The micro-mirror system 200, 300, 400 may further comprise a controller configured to control the electrics comprised in the micro-mirror system. For example, the controller may receive input indicating a required tilt of the mirror and the controller may determine voltages to be applied to each of the electrodes that result in the mirror achieving the required tilt. The controller may use a negative feedback system (using the known position of the mirror determined by the electronics to determine the position of the mirror) to achieve the required tilt of the mirror.

The micro-mirror system 200, 300, 400 may further comprise a voltage source and electrically components such that each electrode (i.e. each of the first electrodes 341, second electrodes 342, third electrodes 343 and fourth electrodes 344) may be provided with a separate voltage.

The first part 201, 301, 401 (comprising the mirror 220, 320, 420) and/or the second part 202, 302, 402 (comprising the substrate 250, 350) of the micro-mirror system 200, 300, 400 may be electrically-grounded. In other words, the first part 201, 301, 401 and/or the second part 202, 302, 402 may be connected (directly, or indirectly i.e. via another connection) to an earth connection or sink for charge.

As can be shown by FIG. 4, the micro-mirror system 400 may further comprise a heat sink 470. The heat sink may comprise a plurality of fins (or otherwise) to increase the surface area to volume ratio to help dissipate or radiate heat energy. For example, the heat sink 470 comprises a plurality of grooves 472 extending into a surface of the heat sink 470. The heat sink 470 may alternatively be referred to as a heat diffuser.

The reflective mirror surface of the mirror may be of any appropriate shape. For example, while the reflective mirror surface 422 is depicted as having a shape of a square in FIG. 4, other shapes, for examples, a circle, triangle or hexagon are possible. Beneficially, shapes (or combination of micro-mirror systems with different shapes) that tessellate may be used to provide a micro-mirror array with a substantially continuous mirror surface. The shape of the substrate 250, 350 may be the same shape as the mirror 220, 320.

When provided as a micro-mirror array, the reflective mirror surface 222, 322, 422 of each micro-mirror system 200, 300, 400 may be a portion of a larger reflective mirror surface. For example, the micro-mirror array may comprise a flexible continuous material (comprising a reflective surface) and the continuous material may be fixed to the actuator of each micro-mirror system 200, 300, 400. By actuation of actuators in each micro-mirror system 200, 300, 400 of the micro-mirror array, the position of the flexible continuous material may be adjusted providing the effect of changing a reflective surface.

In use, in a lithographic apparatus LA, a micro-mirror system (such as the micro-mirror systems 200, 300, 400) may be damaged by hydrogen plasma as discussed above. Gaseous hydrogen may be transported to a space occupied by the electrodes (i.e. electrodes 244, first electrodes 341 or second 342) or other sensitive electronics and, while within the space occupied by the electrodes, the gaseous hydrogen may be exposed to EUV radiation thereby created a hydrogen plasma. Additionally or alternatively, hydrogen plasma may be created elsewhere within the lithographic apparatus LA and be transported to the space occupied by the electrodes. The hydrogen plasma may cause damage by, for example, hydrogen-induced outgassing in micro-mirror systems comprising silicone.

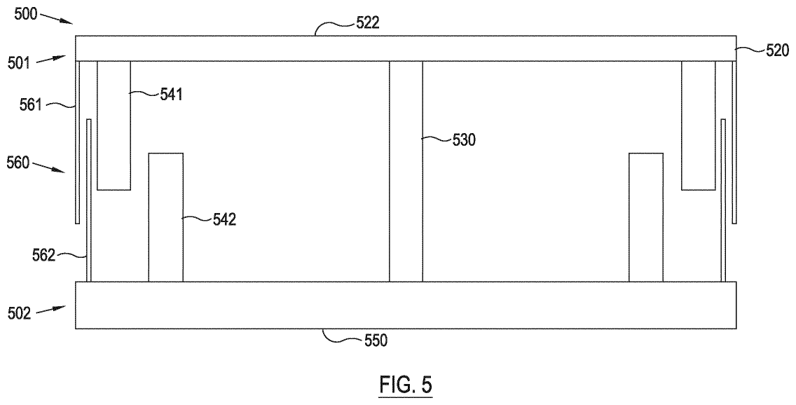

FIG. 5 shows a cross-section view of an example electro-static micro-mirror system 500 substantially the same as the electro-static micro-mirror system 300 (similar components are given likewise reference numerals, for example, central pillar 530 is labelled as 330 in FIG. 3).

As can be seen in FIG. 5, the electro-static micro-mirror system 500 may comprise a first baffle 561. The first baffle 561 is provided as part of the first part 501, but may alternatively be provided as part of the second part 502. The first baffle 561 may be coupled with the first part 501 (comprising the mirror 520) and, optionally, the first baffle 561 may be integrally formed with the first part 501. In other words, the first baffle 561 and the first part 501 may be parts of a single structure. As an example, the first baffle 561 and the first part 501 may comprise silicone. Alternatively, the first baffle 561 may be formed separately to the first part 501.

Beneficially, the first baffle 561 may prevent ingress of a fluid (e.g. gaseous hydrogen or hydrogen plasma) into a space occupied by the first electrode 541 and the second electrode 542. Additionally or alternatively, the first baffle 561 may prevent transmission of radiation (e.g. the EUV radiation beam B) from an environment outside of the MEMS device into a space occupied by the first electrode 541 and the second electrode 542. The first baffle 561 may therefore reduce, or prevent, damage arising from hydrogen plasma.

In examples where the electro-static mirror system 500 further comprises electronics configured to determine the position of the mirror, the space occupied by the first electrode 541 and the second electrode 542 may further comprise the space occupied by the electronics configured to determine the position of the mirror. The first baffle 561 may therefore reduce, or prevent, damage to the electronics configured to determine the position of the mirror arising from hydrogen plasma.

The electro-static micro-mirror system 500 may optionally further comprise a second baffle 562. In other words, the electro-static micro-mirror 500 may comprise a labyrinth seal 560 comprising the first baffle 561 and the second baffle 562. The second baffle 562 is shown coupled with the second part 502 (but more generally is coupled with the one of the first and second parts 501, 502 which the first baffle is not coupled with) and, optionally, the second baffle 562 may be integrally formed with the second part 502. The second baffle 562 may be offset with respect to the first baffle 561 (i.e. not coaxially aligned). That is to say that a central axis of the first baffle 561 is not aligned with a central axis of the second baffle 562.

Advantageously, the labyrinth seal 560 may further reduce, or prevent, damage arising from hydrogen plasma. Beneficially, if a gap (between the first and second baffle 561, 562) is small enough, the first and second baffle 561, 562 may cause charged elements of plasma to recombine.

The first baffle 561 and the second baffle 562 may each be substantially opaque to radiation. For example, the first baffle 561 and the second baffle 562 may have a low transmissivity for EUV radiation.

Each of the first baffle 561 and the second baffle 562 may define a continuous closed loop i.e. in an example where the first baffle 561 is provided on an outer edge of the first part 501, the first baffle 561 may form a perimeter without any gaps around the first part 501. In this way, the first baffle 561 and the second baffle 562 provide a labyrinth seal 560 around the electro-static micro-mirror system 500 such that there are no gaps through which plasma may ingress or through which radiation may be transmitted.

The first baffle 561 and the second baffle 562 may each be long enough (i.e. in a dimension that extends away from the face of the first part 501 and the second part 502, respectively) to ensure there is overlap between ends of the first baffle 561 and second baffle 562. While the first baffle 561 and second baffle 562 are depicted as substantially the same length in FIG. 5, each of the first baffle 561 and the second baffle 562 may be of different lengths (and widths). As discussed, above the first baffle 561 and the second baffle 562 may not be aligned (i.e. the first baffle 561 may be axially aligned with the second baffle 562 and each of the first baffle 561 and second baffle 562 may be provided at different distance from a common axis). In other words, when provided as part of a micro-mirror system 500, a portion of the first baffle 561 encloses a portion of the second baffle 562. Explained differently, the first baffle 561 and second baffle 562 may be symmetric (i.e. the same shape but scaled differently) with respect to a centre of the mirror 520. The spacing (between the first baffle 561 and the second baffle 562) is such that there is a sufficient gap to allow movement of the first part 501 while still preventing ingress of a fluid.

For a typical micro-mirror system 500, the mirror 520 may be 1000×1000×1000 μm and the central pillar 530 may be approximately 100-150 μm long cylinder with a radius of approximately 5 μm. Each of the first electrodes 541 and the second electrodes 542 may be 50 μm long. In such a mirror, each of the baffles (i.e. the first baffle 561 and the second baffle 562) may be (approximately) 1-2 μm wide and 60-70 μm long.

Each of the baffles 561, 562 may be rigid or, alternatively, resilient. Beneficially rigid baffles 561, 562 may provide an ‘end-stop’ i.e. a limit to the allowed movement of the mirror 520.

Each of the first and second baffles 561, 562 may be electrically-grounded. For example, the first baffle 561 and the first part 501 may be integrally formed from identical materials and the first part 501 may be electrically-grounded (by connecting the first part 501 to an earth connection or otherwise). Likewise, the second baffle 562 and the second part 502 may be integrally formed from identical materials and the second part 502 may be electrically-grounded. The first and second baffles 561, 562 may otherwise be electrically-connected such that a voltage of the first baffle 561 is maintained at a voltage of the second baffles 561, 562. Grounding the first and second baffles 561, 562 may advantageously conduct ion-currents and/or photo-currents produced when ions and/or photons, respectively, are blocked thus preventing accumulation of charge.

The labyrinth seal 560 may comprise further baffles. In other words, the first baffle 561 may be one of a plurality of first baffles and/or the second baffle 562 may be one of a plurality of second baffles. Further baffles may advantageously further reduce damage arising from hydrogen plasma.

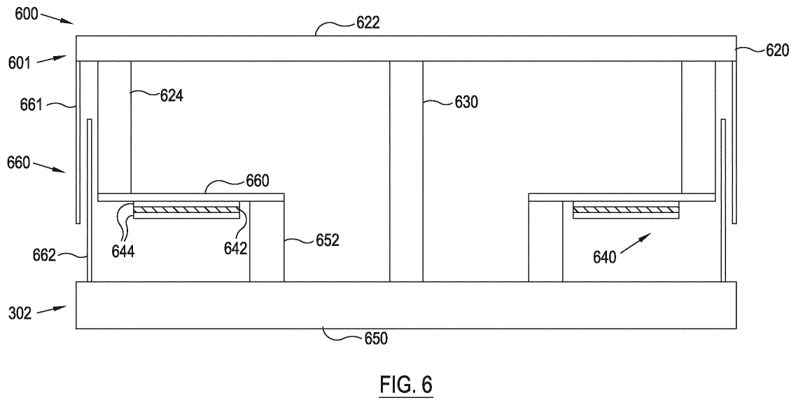

The labyrinth seal 560 may be provided on other micro-mirror systems. FIG. 6 shows a cross-section view of an example piezo-electric micro-mirror system 600. The piezo-electric micro-mirror system 600 is substantially the same as the piezo-electric micro-mirror system 200 as shown in FIG. 2 and similar components in FIG. 6 are given likewise reference numerals. The piezo-electric micro-mirror system 600 further comprises a labyrinth seal 660 comprising first baffle 661 and a second baffle 662. Alternatively or additionally, the micro-mirror systems 500, 600 comprising a labyrinth seal 560, 660 may be provided in inspection and/or metrology apparatus (for example, the dark field apparatus shown in FIG. 1B).

While example micro-mirror systems (e.g. micro-mirror systems 200, 300, 400, 500, 600) have been described herein, as will be clear to the skilled person the baffles (e.g. 561, 562, 661, 662) and/or the labyrinth seal (e.g. 560, 660) may be provided on other MEMS devices. Features of the example micro-mirror systems that have been described have been described for exemplary purposes and such features should not be understood to be essential features of the invention. Additionally while the MEMS devices have been discussed in relation to the example applications of lithographic apparatus, such applications are for exemplary purposes and, as will be clear to the skilled person, the MEMS devices may be used in other applications.

The labyrinth seal 560, 660 and/or the baffles 561, 562, 661, 662 may be manufactured using standard techniques for manufacturing micro-mirror systems known to the skilled person (e.g. by providing a plurality of wafers of silicon, forming elements of the micro-mirror array in the wafers and then bonding the wafers to each other) and the labyrinth seal 560, 660 and/or the baffles 561, 562, 661, 662 may be manufactured by adapting the method accordingly.

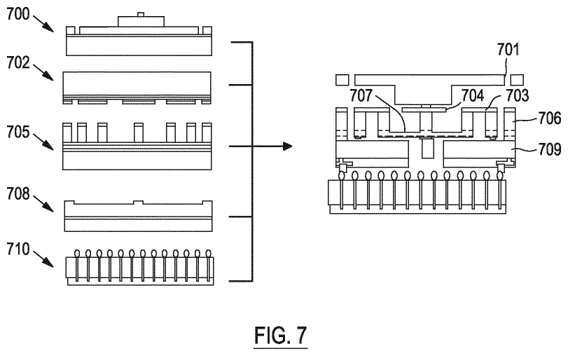

As a first example of a known method for manufacturing a micro-mirror system comprising comb electrodes and a heat diffuser, FIG. 7 shows a schematic diagram of five silicon wafers that are bonded together to form a micro-mirror array. The five wafers comprise a wafer 700 for forming the mirror 701, a wafer 702 for forming upper spring element 703 and optionally for forming flexible connectors 704 of the heat diffuser, a wafer 705 for forming combs 706 of comb (i.e. electro-static) actuators and for forming a lower spring element 707, a wafer 708 being an interposer wafer for providing electrical connections to the micro-mirror array and also for forming a substrate 709 which supports the micro-mirror array, and a wafer 710 for providing electric connections to the interposer wafer 708.

A method of forming the micro-mirror array may comprise the following steps:
a. Providing a first wafer 702 (“upper spring wafer”), which may be a SOI wafer with 1 um highly doped silicon film. The upper spring 703 pattern is formed in the wafer, and optionally also the flexible connectors 704 of the heat diffuser.
b. Providing a second wafer 705 (“comb wafer”) and forming the combs 706 in the second wafer 705. The comb wafer may comprise two SOI wafers bonded together, one SOI wafer having a thin (e.g. 1 um) highly doped silicon film and the other SOI wafer having a thicker (e.g. 30 um) layer of highly doped silicon. Alternatively the comb wafer 705 may comprise one SOI wafer with a thin (e.g. 1 um) highly doped silicon film and, deposited thereon, a highly doped silicon layer (e.g. 30 um thick). The wafer 705 is patterned to form the combs 706 of the comb actuators.
c. Bonding the first wafer 702 to the second wafer 705 so as to to connect the upper spring element 703 to the comb actuator. The step of bonding may comprise fusion bonding with cavities. After bonding, a handle wafer of the second wafer 705 can be removed, followed by via patterning, metal fill and patterning or CMP, and lithography and etching to form the lower spring elements 707.
d. Providing a third wafer 708 (“interposer wafer”), which may be an SOI wafer with a 100 um silicon film. The third wafer 708 is patterned to form cavity holes.
e. Bonding the third wafer 708 to the first and second wafers 702 and 705 so as to connect the comb actuators to the substrate 709. The step of bonding may comprise fusion bonding with cavities. After bonding, a handle wafer of the third wafer 708 may be removed, followed by via etching through the silicon and oxide of the third wafer 708, oxide liner deposition, then further via etching through silicon and oxide into the second wafer 702, TSV Cu fill and CMP, and redistribution layer (RDL) pattern formation on the non-bonded side of the interposer wafer 708.
f. Forming connections to the heat sink and sensing elements. The step of forming connections to the heat sink and to the sensing elements may comprise removing a handle wafer of the first wafer 702, followed by via hole patterning and etching though the highly doped silicon film of the first wafer 702, metal fill and patterning, depositing bonding metal and patterning, and removing the oxide membrane on top of the highly doped silicon film of the first wafer 702.
g. Providing a fourth wafer 700 (“mirror wafer”). The mirror wafer 700 may be an SOI wafer with 250 um silicon film. Providing the mirror wafer 700 may comprise, depositing bonding material and patterning, forming protrusions being capacitor top-plates of the sensing elements, depositing a hard mask and patterning, providing a resist mask and etching silicon (e.g. 100 um etch and over-etch), removing the resist mask and etching the silicon further (e.g. 150 um), and removing the hard mask.
h. Bonding the mirror wafer 700 to the stack of wafers comprising the first wafer 702, the second wafer 705 and the third wafer 708, so as to form the post connecting the mirror to the substrate 709. The bonding may comprise eutectic bonding.
i. Forming bump pads on the third wafer 708 and etching to release the post supporting the mirror 701.
j. Providing a fifth wafer 710 (“electronics wafer”). The step of providing the fifth wafer 710 may comprise providing HV, analog, and digital CMOS components in the electronics wafer, forming TSVs (e.g. 5000 to 10000 connections), and forming bump balls for connecting to the interposer wafer 708.
k. Attaching the electronics wafer 710 to the interposer wafer 708 using the solder bumps on the respective wafers 708 and 710.
l. Removing a handle wafer of the mirror wafer 700 to release the mirror 701, followed by dicing (e.g. laser dicing) to complete the micro-mirror array.

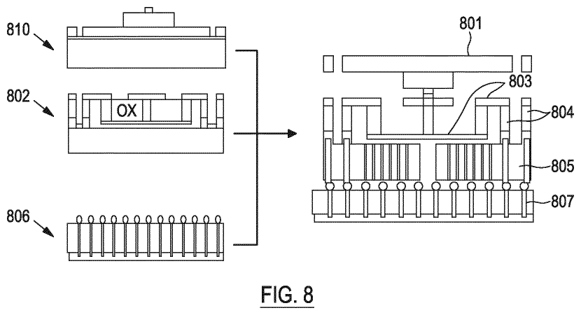

As a second example of a known method for manufacturing a micro-mirror system comprising comb electrodes and a heat diffuser, FIG. 8 shows a schematic diagram of an alternative method of forming a micro-mirror array comprising only three wafers that are bonded together. The three wafers comprise a mirror wafer 810 for forming the mirror 801, a middle wafer 802 for forming spring elements 803, the combs 804 of the comb actuators, and the substrate 805 which supports the micro-mirror array, and an electronics wafer 806 for providing electric connections 807 to the micro-mirror array.

The method of forming the micro-mirror array may comprise the following steps:
a. Providing a first wafer 802 (“middle wafer”). The step of providing may comprise providing an SOI wafer with a 1 um highly doped silicon film, depositing oxide, etching of anchor trenches, filling trenches with polysilicon followed by CMP, patterning oxide to provide a masking layer for the lower spring element 803, and epitaxially growing a 30 um thick silicon layer on the patterned oxide followed by CMP. The step of providing the middle wafer may further comprise, silicon dry reactive ion etching (DRIE) using the oxide as stopping layer, filling the etched silicon with oxide, epitaxially growing a 1 um silicon layer (poly and single crystalline) for the upper spring elements 803, and etching the silicon layer to form the upper spring elements 803. The step of providing the middle wafer may further comprise flipping the wafer, via etching, isolation layer deposition, filling vias with metal and patterning (e.g. to form 5000 to 10000 connections).
b. Providing a second wafer 810 (“mirror wafer”). The mirror wafer 810 may be an SOI wafer with 250 um silicon film. Providing the mirror wafer 810 may comprise, depositing bonding material and patterning, forming protrusions being capacitor top-plates of the sensing elements, depositing a hard mask and patterning, providing a resist mask and etching silicon (e.g. 100 um etch and over-etch), removing the resist mask and etching the silicon further (e.g. 150 um), and removing the hard mask.
c. Bonding the first and second wafers together. The bonding may comprise eutectic bonding.
d. Releasing the spring elements 803 and the combs 804. The step of releasing may comprise forming bump bonding pads (e.g. 10 to 20 per mirror), etching vias through a handle wafer of the first wafer to form space for the movement of the lower spring elements 803 to form a path for subsequent vapor HF etch, etching oxide using vapor HF etch to release the spring element 803 and the combs 804.
e. Providing a third wafer 806 (“electronics wafer”). The step of providing the electronics wafer 806 may comprise providing HV, analog, and digital CMOS components in the electronics wafer, forming TSVs (e.g. 5000 to 10000 connections), and forming bump balls for connecting to the middle wafer 802.
f. Attaching the electronics wafer 806 to the middle wafer 802 using the solder bumps on the respective wafers.
g. Removing a handle wafer of the mirror wafer 810 to release the mirror 801, followed by dicing (e.g. laser dicing) to complete the micro-mirror array.

Although specific reference is made to the use of EUV radiation and to a lithographic apparatus LA comprising the use of EUV radiation, as will be clear to the skilled person, the labyrinth seal 560, 660 (and apparatus comprising the labyrinth seal e.g. the micro-mirror systems 500, 600) may also beneficially be used with, or in systems using, other types of radiation, for example, radiation with a wavelength of 100 nm to 400 nm.

The Figures included herein are schematic figures and any scale between components should not be construed as limiting in anyway. For example, in FIG. 5, while the first baffle 561 and the second baffle 562 are depicted as thinner than the first electrode 541 and the second electrode 542, the first baffle 561 and/or the second baffle 562 may be of any appropriate size (e.g. the first baffle 561 may have a similar width or may be wider than the first electrode 541).

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection and/or metrology apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1-15. (canceled)

16. A micro-electromechanical system, MEMS, device configured to actuate a first part relative to a second part, the MEMS device comprising:
a first electrode and a second electrode configured such that, in use, application of a voltage to the first electrode and the second electrode would cause a force to be applied to the first part relative to the second part; and
a first baffle configured to prevent ingress of a fluid or transmission of radiation from an environment outside of the MEMS device into a space occupied by the first electrode and the second electrode.

17. The MEMS device of claim 16, further comprising a labyrinth seal comprising:
the first baffle, wherein the first baffle is coupled with the first part; and
a second baffle coupled with the second part.

18. The MEMS device of claim 16, wherein:
the first part comprises the first electrode;
the second part comprises the second electrode; and
wherein the force applied to the first part relative to the second part in use is due to a coulomb force created due to the voltage.

19. The MEMS device of claim 16, wherein:
a piezo-electric component is provided between the first electrode and the second electrode; and
the force applied to the first part relative to the second part is due to the piezo-electric component deforming due to the voltage.

20. The MEMS device of claim 16, wherein the first baffle is electrically grounded.

21. The MEMS device of claim 17, wherein the second baffle is electrically grounded.

22. The MEMS device of claim 16, wherein the first part further comprises a mirror, such that the mirror is caused to move in response to the force being applied to the first part relative to the second part.

23. The MEMS device of any claim 16, wherein the first part and the first baffle are integrally formed and the second part and the second baffle are integrally formed.

24. The MEMS device of claim 16, wherein the first baffle is substantially opaque to electromagnetic radiation.

25. The MEMS device of claim 17, wherein the second baffle is substantially opaque to electromagnetic radiation.

26. A micro-mirror array comprising a plurality of the MEMS devices of claim 16.

27. A programmable illuminator comprising a micro-mirror array comprising a plurality of the MEMS devices of claim 16, the micro-mirror array configured to condition a radiation beam.

28. A lithographic apparatus arranged to project a pattern from a patterning device onto a substrate, comprising:
a programmable illuminator comprising a micro-mirror array comprising a plurality of the MEMS devices of claim 16, the micro-mirror array configured to condition a radiation beam used to illuminate the patterning device and/or to condition a radiation beam used to measure a target structure on the substrate.

29. An inspection and/or metrology apparatus, comprising a programmable illuminator comprising a micro-mirror array comprising a plurality of the MEMS devices of claim 16, the micro-mirror array configured to condition a radiation beam used to measure a target structure on a substrate.

30. A method, comprising:
providing a substrate;
forming a first part and a second part;
forming a first electrode and a second electrode configured such that, in use, application of a voltage to the first electrode and the second electrode would cause a force to be applied to the first part relative to the second part; and
forming a first baffle configured to prevent ingress of a fluid or transmission of radiation from an environment outside of the MEMS device into a space occupied by the first electrode and the second electrode.
